(19) United States
(12) Patent Application Publication
(10) Pub. No.: US 2017/0192064 A1
(43) Pub. Date: Jul. 6, 2017

(54) POWER SUPPLY WITH MESSAGE DISPLAY

(71) Applicant: Gary K. PENG, New Taipei City (TW)

(72) Inventor: Gary K. PENG, New Taipei City (TW)

(21) Appl. No.: 15/184,000

(22) Filed: Jun. 16, 2016

(30) Foreign Application Priority Data
Jan. 6, 2016 (TW) TW105200127

(51) Int. Cl. G01R 31/42; G08B 21/18

(52) U.S. Cl. CPC G01R 31/42; G08B 21/182

(57) ABSTRACT

The present invention provides a power supply with message display, including: a power transmission module configured to transmit a power signal, which includes an electrical property data; a detection module configured to receive and detect the electrical property data in the power signal so as to generate and transmit a plurality of detection signals; a control module configured to receive and compute the detection signals so as to generate and transmit a plurality of computational result signals; and, a display module configured to receive the computational result signals, wherein a light signal is displayed by the display module in accordance with the computational result signals. The electrical property data includes current characteristics and voltage characteristics. The power supply with message display of the present invention further includes a casing, a fan module and output ports.

### CROSS-REFERENCE TO RELATED APPLICATION

This application claims the priority of Taiwanese patent application No. 105200127, filed on Jan. 6, 2016, which is incorporated herewith by reference.

### BACKGROUND OF THE INVENTION

1. Field of the Invention

The present invention relates to a power supply, more particularly, relates to a power supply with message display.

2. The Prior Art

As technology advances, desktop or laptop computing devices are often required in the process of manufacturing, production or employment of many new products. Meanwhile, many objects in our daily living environments are also strongly associated with computing devices. Hence, modern people are closely related to computing devices whether at work or life.

The power supply unit (PSU, often referred to as “power supply” or “power”) in a computing device is an electrical power converting type of power (which is different from a batter powered type of power). The power supply in a computing device converts a standard alternating current into a direct current, which has a low voltage and is more stable, for other components in the computer. Currently, most power supplies for use with a computing device on the market are switching power supplies. The voltage input of such supplies automatically adapts to the mains electricity parameters at the user's location.

However, because power supplies for desktop computing devices and industrial computing devices are standard products, besides from supplying electricity to associated components and peripheral products, the power supply itself is not designed with any alert function that is capable of detecting malfunction or irregularities during operation. Thus, computing devices with conventional power supplies are not able to report product status to the users as a timely reminder.

Based on the above reasons, there is a need for the industry to develop a power supply with fault detection features that reports to the user in time, so the user can deal with any functional problems of the product immediately.

### SUMMARY OF THE INVENTION

In view of the drawbacks described above, the present invention provides a power supply with message display, including: a power transmission module configured to transmit a power signal, wherein the power signal includes an electrical property data; a detection module configured to receive and detect the electrical property data in the power signal so as to generate and transmit a plurality of detection signals; a control module configured to receive and compute the detection signals so as to generate and transmit a plurality of computational result signals; and, a display module configured to receive the computational result signals. A light signal is displayed by the display module in accordance with the computational result signals. The electrical property data includes current characteristics and voltage characteristics.

In addition, the power supply with message display of the present invention further includes a casing, a fan module and a plurality of output ports.

Preferably, the power transmission module, the detection module, the control module and the display module are disposed on a circuit board, or are disposed on a plurality of circuit boards.

Preferably, each of the power transmission module, the detection module, the control module and the display module are disposed on different ones of a plurality of circuit boards.

Preferably, the detection signals include an electrical property detection signal, a power load detection signal, a reciprocating interruption detection signal and/or a temperature detection signal.

Preferably, the detection signals include an electrical property detection signal, a power load detection signal, a reciprocating interruption detection signal, a temperature detection signal, an operation detection signal of the fan module and/or a life detection signal of the fan module.

Preferably, the power supply is mounted in a desktop apparatus or a mobile apparatus.

Preferably, the display module is one of a LED light module, a seven-step LED display module and a LCD display module.

Preferably, the light signal is one of a lit light, an off light and a blinking light.

### BRIEF DESCRIPTION OF THE DRAWINGS

Other purposes, advantages and innovative features of the present invention will be apparent to those skilled in the art by reading the following examples with reference to the appended drawings.

FIG. 1 is a block diagram illustrating a configuration of a power supply with message display in accordance with a first embodiment of the present invention; and

FIG. 2 is a perspective view illustrating the power supply with message display in accordance with a second embodiment of the present invention.

### DETAILED DESCRIPTION OF THE PREFERRED EMBODIMENT

The accompanying drawings are included to provide a further understanding of the invention, and are incorporated in and constitute a part of this specification.

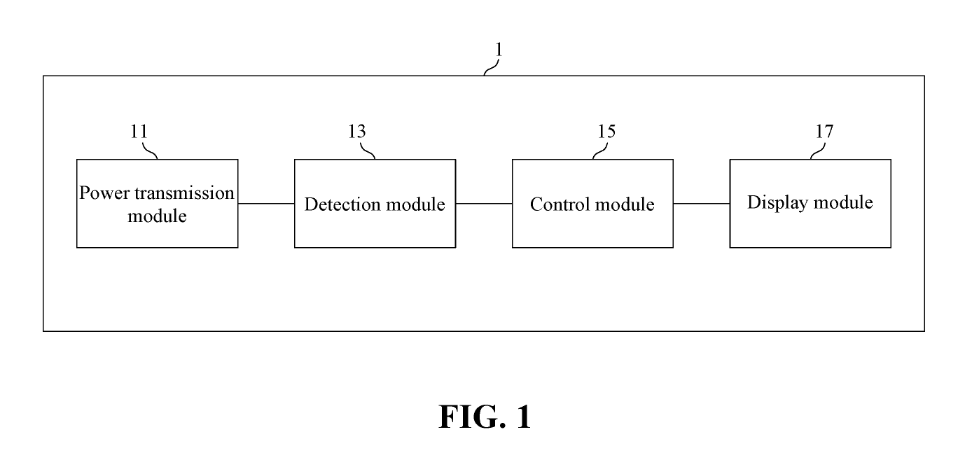

FIG. 1 is a block diagram illustrating a configuration of a power supply with message display in accordance with a first embodiment of the present invention. Referring to FIG. 1, the power supply 1 with message display according to the first embodiment of the present invention includes a power transmission module 11, a detection module 13, a control module 15 and a display module 17. The power transmission module 11 is configured to transmit a power signal (not shown), which includes an electrical property data. The detection module 13 is configured to receive and detect the electrical property data in the power signal so as to generate and transmit a plurality of detection signals. The control module 15 is configured to receive and compute the detection signals so as to generate and transmit a plurality of computational result signals. The display module 17 is configured to receive the computational result signals, and a light signal is displayed by the display module in accordance with the computational result signals.

In the first embodiment of the present invention, the power transmission module 11 is configured to convert an external alternating current (AC) into a direct current (DC), and is also configured to output the power signal. The power signal generated by the power transmission module 11 includes an electrical property data, which includes current characteristics and voltage characteristics. Then, detection module 13 receives and detects the electrical property data in the power signal so as to generate a plurality of detection signals. The detection signals include an electrical property detection signal, a power load detection signal, a reciprocating interruption detection signal and/or a temperature detection signal. Subsequently, the control module 15 receives and computes the detection signals so as to generate and transmit a plurality of computational result signals. At last, the display module 17 receives the computational result signals, and a light signal is displayed by the display module according to the computational result signals. In such a way, the user may determine if the power supply 1 is in operation, or determine if any malfunction has occurred. The display module 17 may be one of a LED light module, a seven-step LED light module and a LCD display module. The light signal may be one of a lit light, an off light and a blinking light.

In other words, the power supply 1 according to the first embodiment of the present invention is configured to detect the electrical property in the power signal transmitted by the power transmission module 11 via the detection module 13, so the detection module 13 may generate an electrical property detection signal, a power load detection signal, a reciprocating interruption detection signal and/or a temperature detection signal. Subsequently, the detection module 13 transmits the abovementioned detection signals to the control module 15, so the electrical property detection signal, the power load detection signal, the reciprocating interruption detection signal and/or the temperature detection signal may be computed by the control module 15 to determine if there is any irregularities in the power signal transmitted by the power transmission module 11. Lastly, the display module 17 is deployed to receive the computational result signals transmitted by the control module 15, so the display module 17 may report any irregularities found in the power supply 1 to the user via the light signal.

On the other hand, in the first embodiment of the present invention, the power transmission module 11, the detection module 13, the control module 15 and the display module 17 may be disposed on one single circuit board, or may be disposed on several circuit boards. In other embodiments of the present invention, the power transmission module 11, the detection module 13, the control module 15 and the display module 17 may be disposed on different ones of several circuit boards. In addition, the power supply 1 with message display may be mounted in a desktop apparatus or a mobile apparatus.

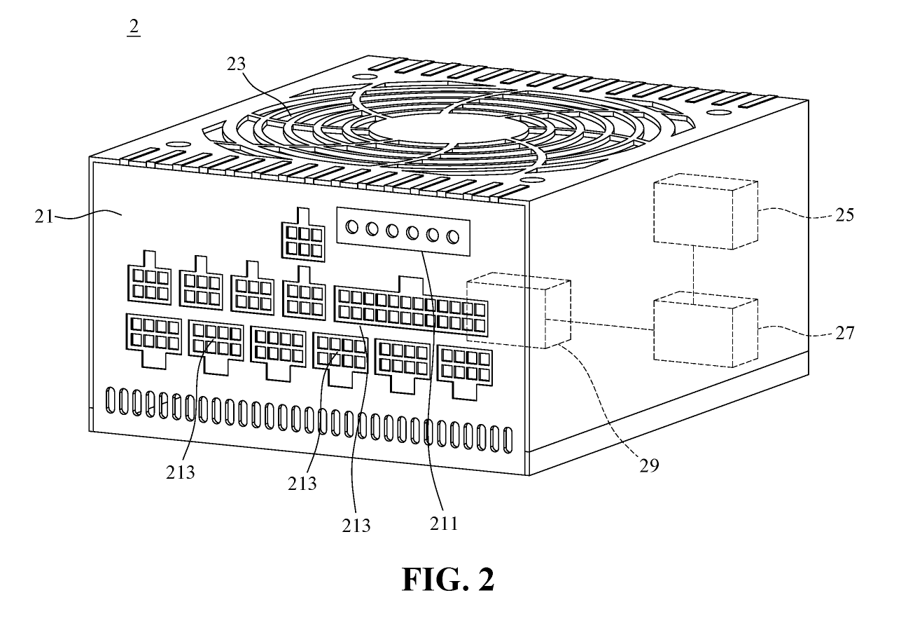

FIG. 2 is a perspective view illustrating a configuration of a power supply with message display in accordance with a second embodiment of the present invention. As shown in FIG. 2, the power supply 2 with message display according to the second embodiment of the present invention includes a casing 21, a fan module 23, a power transmission module 25, a detection module 27, a control module 29, a display module 211 and a plurality of output ports 213. The power transmission module 25 is configured to transmit a power signal (not shown), which includes an electrical property data. The detection module 27 is configured to receive and detect the electrical property data in the power signal so as to generate and further transmit a plurality of detection signals. The control module 29 is configured to receive and compute the detection signals so as to generate and transmit a plurality of computational result signals. The display module 211 is configured to receive the computational result signals, and a light signal is displayed by the display module in accordance with the computational result signals. The power transmission module 25, the detection module 27 and the control module 29 are mounted in the casing 21. The display module 211 may be one of a LED light module, a seven-step LED light module and a LCD display module. The output ports 213 may be connected to other components installed in the computing device via several transmission cables, such as a hard drive, a graphics card and a motherboard. Alternatively, the output ports 213 may be connected to other peripheral devices of the computing device.

In the second embodiment of the present invention, the power transmission module 25, the detection module 27 and the control module 29 are mounted in the casing 21. The fan module 23 serves to dissipate heat for the power supply 2 with message display. The power transmission module 25 is configured to convert an external alternating current (AC) into a direct current (DC), and is also configured to output the power signal. The power signal generated by the power transmission module 25 includes an electrical property data, which includes current characteristics and voltage characteristics. Then, the detection module 27 receives and detects the electrical property data in the power signal so as to generate a plurality of detection signals. The detection signals include an electrical property detection signal, a power load detection signal, a reciprocating interruption detection signal, a temperature detection signal, an operation detection signal of the fan module and/or a life detection signal of the fan module. Subsequently, the control module 29 receives and computes the detection signals so as to generate and further transmit a plurality of computational result signals. At last, the display module 211 receives the computational result signals, and a light signal is displayed by the display module according to the computational result signals. In such a way, the user may determine if the power supply 1 is in operation, or determine if any malfunction has occurred.

In other words, the power supply 2 according to the second embodiment of the present invention is configured to detect the electrical property in the power signal transmitted by the power transmission module 25 via the detection module 27, so the detection module 27 may generate the electrical property detection signal, the power load detection signal, the reciprocating interruption detection signal, the temperature detection signal, the operation detection signal of the fan module and/or the life detection signal of the fan module. Subsequently, the detection module 27 transmits the abovementioned detection signals to the control module 29, so the electrical property detection signal, the power load detection signal, the reciprocating interruption detection signal, the temperature detection signal, the operation detection signal of the fan module and/or the life detection signal of the fan module may be computed by the control module 29 to determine if there is any irregularities in the power signal transmitted by the power transmission module 25. Lastly, the display module 211 is deployed to receive the computational result signals transmitted by the control module 29, so the display module 211 may report any irregularities found in the power supply 2 to the user via the light signal. The light signal utilized herein may be one of a lit light, an off light and a blinking light.

On the other hand, in the second embodiment of the present invention, the power transmission module 25, the detection module 27, the control module 29 and the display module 211 may be disposed on one single circuit board, or may be disposed on several circuit boards. In other embodiments of the present invention, the power transmission module 25, the detection module 27, the control module 29 and the display module 211 may be disposed on different ones of several circuit boards. In addition, the power supply 2 with message display may be mounted in a desktop apparatus or a mobile apparatus.

As described above, the present invention provides a power supply with message display that is configured to detect the electrical property values (such as voltages and currents) between a main power supply end and a power output end, and is also configured to provide alert messages via a display module. In such a way, users may determine if the product meets the specification provided by the original power supply; in addition, alert notifications for any irregularities found with the power supply may also be provided. Further, besides from providing electrical property detection signals and alert notifications for irregular conditions, the power supply of the present invention is also configured to provide a power load detection signal, a reciprocating interruption detection signal, an operation detection signal of the fan module, a life detection signal of the fan module and/or a temperature detection signal of the inside of the power supply. With the detection module mounted inside the power supply, the control module and the display module, which employs one of a lit light, an off light or a blinking light as its alert method, the power supply of the present invention is able to provide or alert users with the operation conditions of each electrical functions of the power supply in a convenient and timely manner.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A power supply with message display, comprising:
a power transmission module configured to transmit a power signal, wherein the power signal includes an electrical property data;
a detection module configured to receive and detect the electrical property data in the power signal so as to generate and transmit a plurality of detection signals;
a control module configured to receive and compute the detection signals so as to generate and transmit a plurality of computational result signals; and
a display module configured to receive the computational result signals, wherein a light signal is displayed by the display module according to the computational result signals;
wherein the electrical property data includes current characteristics and voltage characteristics.

2. The power supply with message display according to claim 1 further comprising a casing, a fan module and a plurality of output ports.

3. The power supply with message display according to claim 1, wherein the power transmission module, the detection module, the control module and the display module are disposed on a circuit board, or are disposed on a plurality of circuit boards.

4. The power supply with message display according to claim 1, wherein each of the power transmission module, the detection module, the control module and the display module are disposed on different ones of a plurality of circuit boards.

5. The power supply with message display according to claim 1, wherein the detection signals include an electrical property detection signal, a power load detection signal, a reciprocating interruption detection signal and/or a temperature detection signal.

6. The power supply with message display according to claim 2, wherein the detection signals include an electrical property detection signal, a power load detection signal, a reciprocating interruption detection signal, a temperature detection signal, an operation detection signal of the fan module and/or a life detection signal of the fan module.

7. The power supply with message display according to claim 1, wherein the power supply is mounted in a desktop apparatus or a mobile apparatus.

8. The power supply with message display according to claim 1, wherein the display module is one of a LED light module, a seven-step LED display module and a LCD display module.

9. The power supply with message display according to claim 1, wherein the light signal is one of a lit light, an off light and a blinking light.
